(19) United States
(12) Patent Application Publication
(10) Pub. No.: US 2026/0031641 A1
(43) Pub. Date: Jan. 29, 2026

(54) SYSTEMS AND METHODS OF PROVIDING A SAFETY INDICATOR FOR A PORTABLE POWER CHARGER

(71) Applicant: Alliance Sports Group LP, Roanoke, TX (US)

(72) Inventor: Todd Marcucci, Mansfield, TX (US)

(21) Appl. No.: 19/277,904

(22) Filed: Jul. 23, 2025

Related U.S. Application Data
(60) Provisional application No. 63/675,122, filed on Jul. 24, 2024.

(51) Int. Cl. H02J 7/00; G01R 31/385; G01R 31/389; G01R 31/392; G08B 7/06; G08B 21/18; H02J 1/10

(52) U.S. Cl. CPC H02J 7/005; G01R 31/385; G01R 31/389; G01R 31/392; G08B 7/06; G08B 21/185; H02J 1/122; H02J 7/00036; H02J 7/007182

(57) ABSTRACT

A portable power charger is provided. The portable power charger includes a port configured to connect to a cable configured to connect to a battery and a safety circuit. The safety circuit is configured to: a) determine that the port is connected to the battery via the cable; b) determine that one or more battery factors of the battery meet one or more corresponding battery thresholds; and c) determine that one or more power charger factors of the portable power charger meet one or more corresponding power charger thresholds. The portable power charger also includes a a resistance analyzer configured to measure a resistance of the battery and an alert generator configured to generate an alert to signal when the battery is faulty based on the measured resistance.

### CROSS REFERENCE TO RELATED APPLICATIONS

This application claims the benefit of U.S. Provisional Application No. 63/675,122, filed on Jul. 24, 2024, which application is incorporated herein by reference in its entirety.

### BACKGROUND

Various embodiments relate generally to power charging devices and, more specifically, relate to a providing a safety indicator for a portable power charger.

This section is intended to provide a background or context. The description may include concepts that may be pursued, but have not necessarily been previously conceived or pursued. Unless indicated otherwise, what is described in this section is not deemed prior art to the description and claims and is not admitted to be prior art by inclusion in this section.

Car battery chargers on the market are susceptible to various problems, including electrical faults, fault currents and improper connections, which can result in diminished use and durability of many such devices. Additionally, portable power chargers adapted for charging a car battery are typically always “live” in that a charge is always being provided at the outlet to which the jumper cables are connected. As a result, it is easy for a user to accidentally experience a shock. Further, such devices typically are not also usable for recharging portable electronic devices and laptop computers.

In view of the foregoing, there is a need for a portable charger that can be used to charge a car battery while still being easily portable itself. Accordingly, there is a need for such a charger that has high charge capacity—e.g., on the order of 10,000 to 15,000 mAh—while still being portable, of a compact size, and easy to use in various conditions and locations to charge a car battery without compromising operation, performance or appearance. Still further, there is a need for a portable charger system or kit with fail-safes that avoid the connection and electrical problems of conventional power chargers that contribute to shortened use and durability of the portable charger. Accordingly, it is a general object of the present invention to provide a portable charger system or kit that improves upon conventional power chargers currently on the market, especially car battery chargers, and that overcomes the problems and drawbacks associated with such prior art chargers.

See further U.S. Pat. Nos. 9,318,915, 10,075,000 and 10,840,716, of which each application is incorporated herein by reference in their entirety.

### SUMMARY

Example aspects of the present disclosure include:

A portable power charger according to at least one embodiment of the present disclosure comprises a port configured to connect to a cable configured to connect to a battery; a safety circuit configured to: a) determine that the port is connected to the battery via the cable; b) determine that one or more battery factors of the battery meet one or more corresponding battery thresholds; and c) determine that one or more power charger factors of the portable power charger meet one or more corresponding power charger thresholds; a resistance analyzer configured to measure a resistance of the battery; and an alert generator configured to generate an alert to signal when the battery is faulty based on the measured resistance.

Any of the aspects herein, further comprising a display configured to display the alert, wherein the alert comprises at least one of: a visual alert and text.

Any of the aspects herein, wherein the alert comprises an indication of at least one of the battery is faulty and the battery is acceptable.

Any of the aspects herein, wherein the display also displays an indication of an assessment of an acceptability of the battery.

Any of the aspects herein, wherein the safety circuit is further configured to generate an assessment level of acceptability of the battery, and wherein the safety circuit is configured to determine that the battery is healthy when the assessment level meets a threshold.

Any of the aspects herein, further comprising a speaker configured to play the alert, wherein the alert comprises at least one of: an audible alarm, a tone, and a simulated or real voice.

Any of the aspects herein, wherein the resistance analyzer is configured to determine that the battery is faulty based on a) at least one of: a quantitative and qualitative measurement and b) a subsequent indicator.

Any of the aspects herein, wherein determining that the battery is faulty comprising determining that the battery is at least one of: defective and requires reconditioning.

Any of the aspects herein, wherein the battery is determined to be faulty when the measured resistance meets a resistance threshold.

Any of the aspects herein, further comprising a wireless communication system configured to perform remote monitoring of the portable power charger and the battery.

Any of the aspects herein, wherein the wireless communication system is at least one of: a Bluetooth system and a Wi-Fi system.

Any of the aspects herein, wherein the portable power charger is at least one of: a portable jump starter and a device charger.

A portable vehicle power bank according to at least one embodiment of the present disclosure comprises a jumper-cable port configured to be connected to a vehicle battery; a safety circuit configured to confirm that: a) the port is properly connected to the vehicle battery;
b) the vehicle battery is healthy; and c) the portable vehicle power bank is of sufficient health and capacity, a voltage analyzer configured to measure a voltage of the vehicle battery; and an alert generator configured to generate an alert to signal when the battery is faulty based on the measured voltage.

Any of the aspects herein, wherein determining that the battery is faulty comprising determining at least one of: a) the voltage is outside a predetermined battery operation range for proper operation of a functioning battery, and b) the voltage is outside of a predetermined alternators operation range for proper operation for alternators.

Any of the aspects herein, wherein the predetermined battery operation range is between 11.5 and 12.5V.

Any of the aspects herein, wherein the vehicle battery has a chemistry of one of: flooded/wet lead acid, SLA, AGM, 4-cell or similar regulated lithium.

Any of the aspects herein, wherein the predetermined alternators operation range is between 13.5V and 15.0V.

A safety adapter according to at least one embodiment of the present disclosure comprises a safety circuit in communication with a battery and a portable power charger, the safety circuit configured to: a) determine that one or more battery factors of the battery meet one or more corresponding battery thresholds; and c) determine that one or more power charger factors of the portable power charger meet one or more corresponding power charger thresholds; a resistance analyzer configured to measure a resistance of the battery; and an alert generator configured to generate an alert to signal when the battery is faulty based on the measured resistance.

Any of the aspects herein, wherein the safety circuit is in at least one of wired communication and wireless communication with the battery and the portable power charger.

A safety device according to at least one embodiment of the present disclosure comprises a port configured to connect to a cable configured to connect to a vehicle diagnostic port of a vehicle on-board system, the vehicle on-board system connected to a battery; a safety circuit in communication with a battery configured to: a) determine that the port is connected to the battery via the cable; b) determine that one or more battery factors of the battery meet one or more corresponding battery thresholds; and c) determine that one or more power charger factors of the portable power charger meet one or more corresponding power charger thresholds; d) monitor diagnostic information from the vehicle diagnostic port; and e) generate and transmit instructions to the portable power charger to at least one of inhibit or suspend an associated trickle charge when the diagnostic information precludes the charging operation; and a resistance analyzer configured to measure a resistance of the battery; and an alert generator configured to generate an alert to signal when the battery is faulty based on the measured resistance.

Any of the aspects herein, wherein the diagnostic information comprises at least one or more codes, errors, or shut-off conditions.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/embodiments in combination with any one or more other aspects/features/embodiments.

Use of any one or more of the aspects or features as disclosed herein.

It is to be appreciated that any feature described herein can be claimed in combination with any other feature(s) as described herein, regardless of whether the features come from the same described embodiment.

The details of one or more aspects of the disclosure are set forth in the accompanying drawings and the description below. Other features, objects, and advantages of the techniques described in this disclosure will be apparent from the description and drawings, and from the claims.

The phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

The term “a” or “an” entity refers to one or more of that entity. As such, the terms “a” (or “an”), “one or more” and “at least one” can be used interchangeably herein. It is also to be noted that the terms “comprising”, “including”, and “having” can be used interchangeably.

The preceding is a simplified summary of the disclosure to provide an understanding of some aspects of the disclosure. This summary is neither an extensive nor exhaustive overview of the disclosure and its various aspects, embodiments, and configurations. It is intended neither to identify key or critical elements of the disclosure nor to delineate the scope of the disclosure but to present selected concepts of the disclosure in a simplified form as an introduction to the more detailed description presented below. As will be appreciated, other aspects, embodiments, and configurations of the disclosure are possible utilizing, alone or in combination, one or more of the features set forth above or described in detail below.

Numerous additional features and advantages of the present disclosure will become apparent to those skilled in the art upon consideration of the embodiment descriptions provided hereinbelow.

### BRIEF DESCRIPTION OF THE DRAWINGS

Aspects of the described embodiments are more evident in the following description, when read in conjunction with the attached Figures.

FIG. 1 shows a perspective view of a control unit according to at least one embodiment of the present disclosure.

FIG. 2 shows a simplified block diagram of internal components of an embodiment of a portable power charger according to at least one embodiment of the present disclosure.

FIG. 3 shows a front, top perspective view of a first embodiment of a portable power charger according to at least one embodiment of the present disclosure.

FIG. 4 shows a perspective view of a second embodiment of a portable power charger according to at least one embodiment of the present disclosure.

FIG. 5 shows a flowchart according to at least one embodiment of the present disclosure.

### DETAILED DESCRIPTION

Various embodiments provide an indication to the user when a portable power charger is not properly setup. For example, the portable power charger may provide a warning when attached to a battery (e.g., a vehicle battery) if 1) the battery is defective, 2) the battery is weak (independent of a defect), and/or 3) the alternator appears to be working. The defects may be checked using hardware and/or software. The warnings, when detected by the portable power charger may be shown on a detailed display data, or coupled with warning LEDs on the housing.

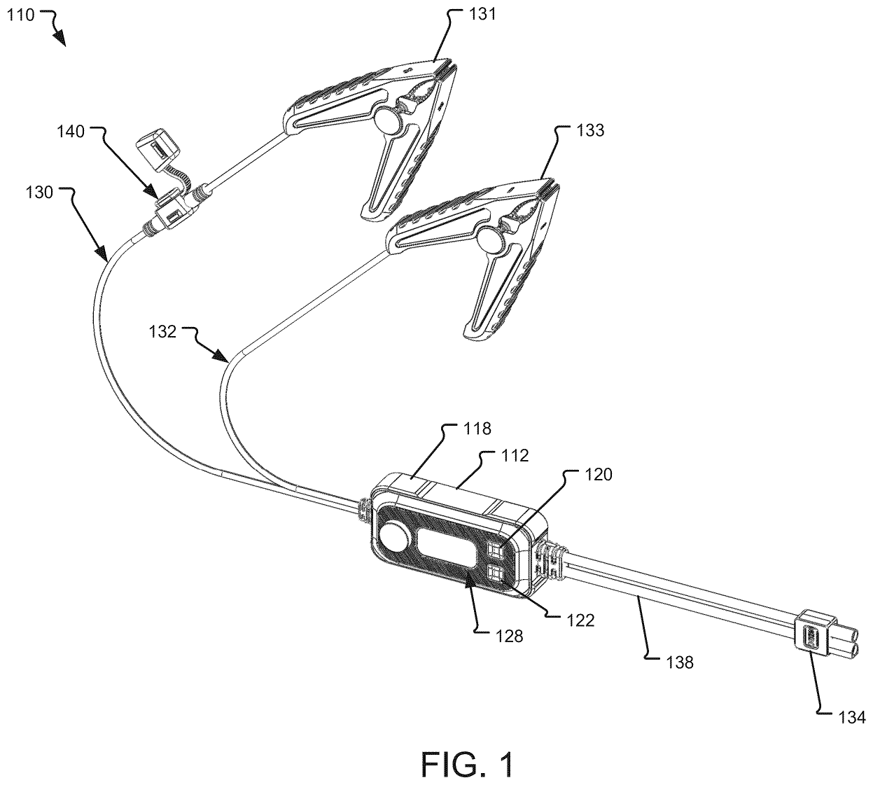

FIG. 1 shows a portable power charger (110) including a control unit (112). The portable power charger (110) can be used in many applications such as, for example, to jump start a vehicle battery and/or charge portable electronic devices. The vehicle battery can be, for example, a 12V or a 24V vehicle battery, though in other embodiments, the vehicle battery can be any voltage greater than or less than 12V. Similarly, the portable electronic devices may be 5V, though in other embodiments, the portable electronic devices can be greater than or less than 5V. In any instance, the portable power charger (110) can be used to charge or provide power to any device and/or component at any charge.

As shown, the control unit (112) has a housing (118). The housing (118) includes a jump-start button (120), a power button (122), and a display (128). The display can include, for example, an LCD, an LED, and/or a combination of LED alerts. The housing (118) can also include a lamp (e.g., an LED or fluorescent lamp) on an external portion of the housing (118). The housing (118) may include more or less buttons and/or indicators in other embodiments. For example, the housing (118) may include a flashlight, one or more receivers, additional ports (for receiving, for example, charging cables), a display screen, a touch screen, etc. In another example, the housing (118) may not include the lamp (128), the battery safety charge state indicator LED (124), etc.

The housing (118) also includes positive and negative jumper cables (130), (132) extending from the housing (118). The jumper cables (130), (132) can be rated to voltages of, for example, 12V or 24V, or any other voltage value. The jumper cables (130), (132) include connectors (131), (133) at an end of each jumper cable (130), (132) to connect the jumper cables (130), (132) to, for example, terminals of a battery. The connectors (131), (133) may be, for example, clips, clamps, alligator clips, or any other connector capable of connecting to one or more terminals on a battery. At least one of the jumper cables (130), (132) also includes a fuse (140) inline with the corresponding connectors (131), (133). In the illustrated embodiment, the fuse (140) is inline with the jumper cable (130). In other embodiments, the fuse (140) may be inline with the jumper cable (132), or each of the jumper cables (130), (132) may have a fuse.

Also extending from the housing (118) are one or more cables (138) that each have a corresponding connector (134) at the end of each cable (138). In the illustrated embodiment, the connector (134) is an EC3 connector. In other embodiments, the connector (134) may be an EC5 connector, a combination of connectors (e.g., an EC3 connector and/or an EC5 connector), or any other connector configured to connect the control unit (112) with an external power source (not shown). The external power source may be used to provide a battery output to, for example, the jumper cables (130), (132) via the portable power charger (110) in a pass-through configuration. In such configuration (and in any other configuration described herein) power received from the external power source may be converted into a suitable format (e.g., converting voltage and/or power) for the jumper cables (130), (132). The battery output may be 12V, though in other embodiments the battery output may be greater than or less than 12V. The external power source may be, for example, power from an AC source, power from a DC source, power from a USB source, solar power from a solar panel, an external battery, or the like. The external power source may be, for example, a portable power source or wall power. In some embodiments, the connector (134) may be integrated with a mechanical connection capable of securing the external power bank to the portable power charger (110).

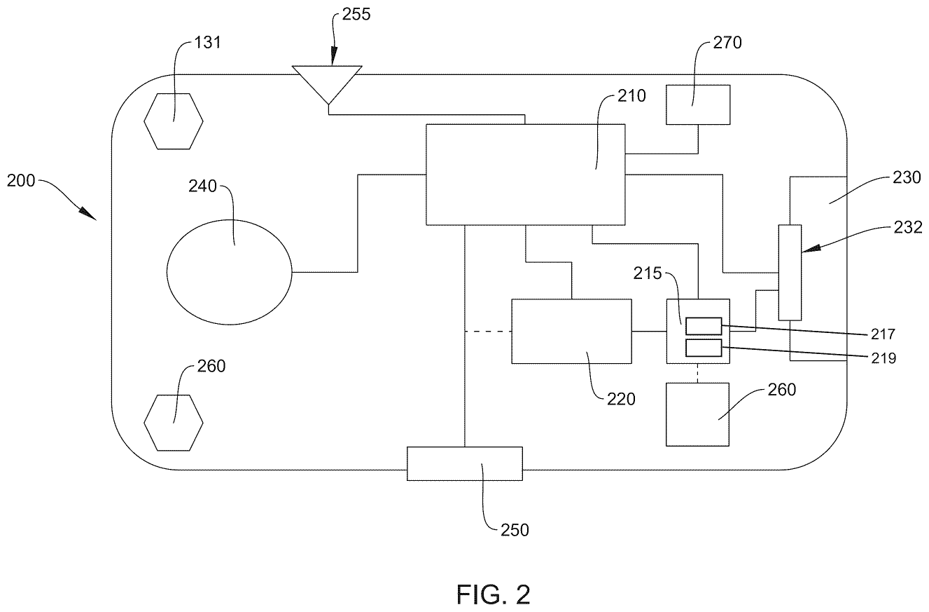

Inside the housing (118), the control unit (112) houses a safety circuit (215) (labelled and shown in FIG. 2) that operatively connects an internal power storage unit (220) (also labelled and shown in FIG. 2) with the jumper cables (130), (132). The safety circuit (215) may also connect the external power source (connected via the connector (134)) to the jumper cables (130), (132). The safety circuit (215) may be, for example, an integrated circuit or microchip capable of processing and storing information regarding the internal power storage unit (220), a battery connected via the jumper cables (130), (132), and/or the external power source connected via the connector (134).

Generally, the safety circuit (215) enables operative connection of the jumper cables (130), (132) with the internal power storage unit (220) when a voltage differential meets or is greater than a voltage differential threshold across the positive and negative jumper cables (130), (132). In some embodiments, the voltage differential threshold is at least about 11V, though in other embodiments, the voltage differential threshold may be greater than or less than 11V. Such voltage differential threshold does not enable the jumper cables (130), (132) to produce a live output when not connected to, for example, a battery, thereby beneficially preventing accidental discharge of a current to a user. Additionally, the safety circuit (215) may also determine that the voltage is less than a predetermined voltage threshold to, for example, prevent back-feeding into the portable power charger (110) and/or the prevent possible damage to the battery or any other component.

The safety circuit (215) also interrupts at least the operative connections of the jumper cables (130), (132) with the internal power storage unit (220) when a shut off condition occurs. The shut off condition may include, for example: insufficient voltage across the positive and negative jumper cables (130), (132); reverse polarity of the positive and negative jumper cables (130), (132); reverse current to the internal power storage unit (220); undesired resistance measurement; or excess temperature of the internal power storage unit (220). The shut off conditions may include other conditions not listed here. The shut off conditions may be monitored based on user input or continuously. In embodiments where the shut off conditions are monitored based on user input, the safety circuit (215) may initiate a jump-start safety check sequence to check for one or more shut off conditions in response to a user actuation of the jump-start button (120). In embodiments where the shut off conditions are monitored continuously, the shut off conditions may be checked at a time interval such as, for example, every second, every minute, every hour, or the like.

The safety circuit (215) can operate autonomously, semi-autonomously, or manually (e.g., with input from a user). In embodiments where the safety circuit (215) operates autonomously or semi-autonomously, the safety circuit (215) can execute the various operations (such as, for example, interruptions) while using the internal power storage unit (220) as a battery.

In some embodiments, the safety circuit (215) can communicate and coordinate with the external power source (for example, one connected via connector (134)) to perform a safety check sequence and associated functionality as well as other communication functions. For example, the control unit (112) can coordinate the supply of charge so that the internal power storage unit (220) is not always supplying a live output such as, for example, a live output of 12V, 24V, etc.

Additionally, the safety circuit (215), a supplemental safety circuit, or a combination of both may act to confirm if the connectors (131), (133) of the jumper cables (130), (132) are in proper placement on, for example, battery terminals of a vehicle battery. If the connectors (131), (133) are properly placed on the battery terminals, the safety circuit (215) and/or the supplemental safety circuit may switch on power fed to the connectors (131), (133) through the jumper cables (130), (132) via the control unit (112). In some embodiments, the connectors (131), (133) and the jumper cables (130), (132) are auto-sensing spark preventing connectors (131), (133) containing sensing circuitry that is activated based on the clip clamp/teeth design. Accordingly, connectors (131), (133) which are not properly connected to the vehicle battery terminals are not able to supply a current to the vehicle battery terminals

The safety circuit (215) of the control unit (112) may also communicate and coordinate with the internal power storage unit (220) to adjust a feed of power or to shut off the internal power storage unit (220) if the vehicle battery is recharged or a shut off condition is sensed.

In at least one embodiment, the internal power storage unit (220) and/or the external power source can be a series-connected three-cell lithium-ion polymer battery rated at 3.7V per cell (11.1V total), capable of 400 A peak current, in excess of 57000 mWh capacity, with charging circuitry to support a charge voltage of 19V. Such specifications enable the portable power charger (110) to be of moderate size, such as, less than 30 cm along any edge, while also being capable of at least three jump start attempts on a 12V car battery. Such power supply allows up to 400 A of peak current to be drawn for jump-starting an automotive battery that is connected to a vehicle. Additionally, the power supply provides 5V DC output to the USB jacks for charging, for example, personal electronic devices. It will be appreciated that in other embodiments, the internal power storage unit (220) and/or the external power source can be any battery with any rating.

During use of the portable power charger (110), after actuation of the jump-start button (120) and upon successful completion of the jump-start safety check sequence, the portable power charger (110) provides 12V DC current from the internal power storage unit (220) and/or the external power source to the jumper cables (130), (132) and the connectors (131), (133). Moreover, upon completion of the jump-start safety check sequence the internal power storage unit (220) and/or the external power remains ready to provide 12V DC current for a pre-determined period of time. It will be appreciated that in other embodiments, the internal power storage unit (220) and/or the external power can provide any rating and/or type of current. In at least one example, during a pre-determined period of time, the portable power charger (110) can provide 12V DC current from the internal power storage unit (220) and/or the external power to the jumper cables (130), (132) and the connectors (131), (133) in response to a second user actuation of the jump-start button (120). In other words, multiple discrete jump-start attempts can occur during the pre-determined period of time. According to certain embodiments, the portable power charger (110) discontinues readiness after three discrete jump-start attempts.

Turning to FIG. 2, a simplified block diagram of internal components of an embodiment of a portable power charger (200) is provided. The portable power charger (200) may be the same as or similar to the portable power charger (110). Similarly, the portable power charger (110) may include the same or similar components as the portable power charger (200). For example, the portable power charger (110) includes the internal power storage unit (220), as described above.

The portable power charger (200) includes the internal power storage unit (220), such as a battery, which can be managed via a control unit (210). The control unit (210) may be the same as or similar to the control unit (112). The control unit (210) may include, for example, a controller, the safety circuit (215), a microcontroller, etc. The control unit (210) may also control energy transfer to/from one or more ports (232) and a wireless connection (240). An input/output (250) is also provided which can show information regarding the portable power charger (200) and the power storage unit (220). For example, the input/output (250) can signal whether the battery is faulty based on a current state of the battery. Such input/output (250) may be, for example, a visual alert, a text, an audible alarm, a tone, a voice, etc. Magnets (260) are shown which can help ensure connection to an attachment device.

The ports (232) may be housed within a storage area (230) capable of holding, for example, connector cables (such as cable (138)). In some embodiments, the connector cables may be directly connected to the ports (232).

The safety circuit (215) may be connected to the power storage unit (220) and to the ports (232). The safety circuit (215) may, for example, ensure proper connection of jumper cables (130), (132) attached to the port (232) before allowing power to flow from the power storage unit (220) to the port (232) as previously described. The safety circuit (215) may also communicate with the control unit (210), for example, to receive instructions and/or to provide warnings. The control unit (210) may then display an associated warning on a display of the input/output (250).

The safety circuit (215) may also analyze a connected battery to determine if the connected battery is properly connected and healthy. Such determination of whether the connected battery is healthy may be based on, for example, a temperature and/or a capacity of the connected battery. The determination may also be based on, for example, conducting a load test and/or measuring a voltage, an impedance, a resistance, a current, etc. of the connected battery. Similarly, a condition or health of the internal power storage unit (220) may be determined by the safety circuit (215). For example, a temperature and/or a capacity may be checked, a load test may be conducted and/or a voltage, an impedance, a resistance, a current, etc. may be measured of the internal power storage unit (220).

If the battery is properly connected and healthy and the internal power storage unit (220) is also healthy, the safety circuit (215) may allow the portable power charger (200) to charge the connected battery via the internal power storage unit (220) or an external power source connected to the portable power charger (200). The charging (also referred to as an “associated charge”) may be a slow charge, for example, using a trickle charge, or a fast charge. The charging may be, for example, equal to or less than 1 A, 1.5 A, or 5 A. In other embodiments, the charge may be greater than 1 A, 1.5 A, or 5 A. In some embodiments, the charging may be, for example, 100 W, 120 W, 150 W, or 200 W. In other embodiments, the charging may be less than or greater than 100 W, 120 W, 150 W, or 200 W, depending on, for example, a USB or DC input limitations.

In some embodiments, a user may select the type of battery connected to the portable power charger (200) using the input/output (250). In such embodiments, the safety circuit (215) may base the analysis of the connected battery and the proper charge on the selected battery type. The battery type may be, for example, a wet lead acid, a sealed lead acid (SLA), and an absorbed glass-mat (AGM).

The safety circuit (215) may include a resistance analysis circuit (217) to measure and/or analyze a resistance of a connected battery and/or a voltage analysis circuit (219) to measure and/or analyze a voltage of a connected battery. The resistance analysis circuit (217) may determine if the connected battery has an internal resistance indicative of proper operation. For example, the resistance analysis circuit (217) may determine that the resistance meets or exceeds a predetermined resistance threshold. If the resistance does not meet or exceed the predetermined resistance threshold, then the resistance analysis circuit (217) may determine that the connected battery is faulty. Likewise, the voltage analysis circuit (219) may determine if the connected battery has a voltage indicative of proper operation. For example, the voltage may be within an acceptable range for the battery (such as, between 11.5 to 12.5V). The voltage analysis circuit (219) may also determine if the connected battery has a voltage outside a range indicative of proper operation for a traditional alternator (such as, less than 13.5V or more than 15.0V).

When analyzing the battery, the safety circuit (215) may determine a degree of health, for example, “good health”, “acceptable” or “faulty”. The degree of health may be determined by how well the battery meets various measurements and/or factors. The measurements and/or factors may be received from or determined using one or more codes obtained from the battery and/or the portable power charger (200). Threshold values may be assigned to assess battery output voltage or amperage. Based on the thresholds the battery meets (either taken individually or in combination), a degree of health may be assessed for the battery. The degree may be represented by levels (good, acceptable, faulty, etc.) or as a percentage. The safety circuit (215) may indicate the battery is faulty when it fails to meet given thresholds, for example, not reaching “acceptable”, not meeting the predetermined resistance threshold, and/or not meeting a predetermined voltage threshold.

The safety circuit (215) may then provide the battery assessment information to be shown on the display (250). This may be shown as a series of lights (e.g., colored LEDs, blinking lights, etc.) or as an indicator on a screen, such as a percentage or description of the issue. The display (250) may also indicate a corrective action or remedy for the fault, for example, “replace battery”, “check connection”, etc.

The portable power charger (200) may also include a charging circuit (260). The charging circuit (260) can be, for example, an integrated circuit or microchip capable of processing and storing information to determine a current state of a connected battery based on analysis from the safety circuit (215). The analysis may be, for example, the determination of whether the connected battery is properly connected and healthy, as described above. Once the current state is determined, the charging circuit (260) can provide an associated charge to the vehicle battery based on the current state. The associated charge may be, for example, a trickle charge. The associated charge may be indicated by a pre-determined charging curve/current for the determined current state of the battery (and battery type).

The portable power charger (200) may also include a wireless communication connection (270). The wireless communication connection (270) may be configured to allow wireless monitoring of the portable power charger (200). The wireless communication connection (270) may operate with any suitable wireless technology and/or protocol, such as, Bluetooth, Wi-Fi, NFC, etc.

Using the wireless communication connection (270), the portable power charger (200) may provide information for display. The information may be the same as shown on the display (250) and/or it may include additional details. For example, the portable power charger (200) may indicate a faulty battery is connected and send details regarding the fault, such as a measured voltage, etc.

Various components may be incorporated into a single element. For example, the control unit (210) may include the safety circuit (215) and the charging circuit (260). Additionally, components may be separated into multiple parts, for example, input/output (250) may be divided into an input device and a separate output device. Further, the portable power charger (200) may have more or less components than shown. For example, the portable power charger (200) may not include the wireless communication connection (270).

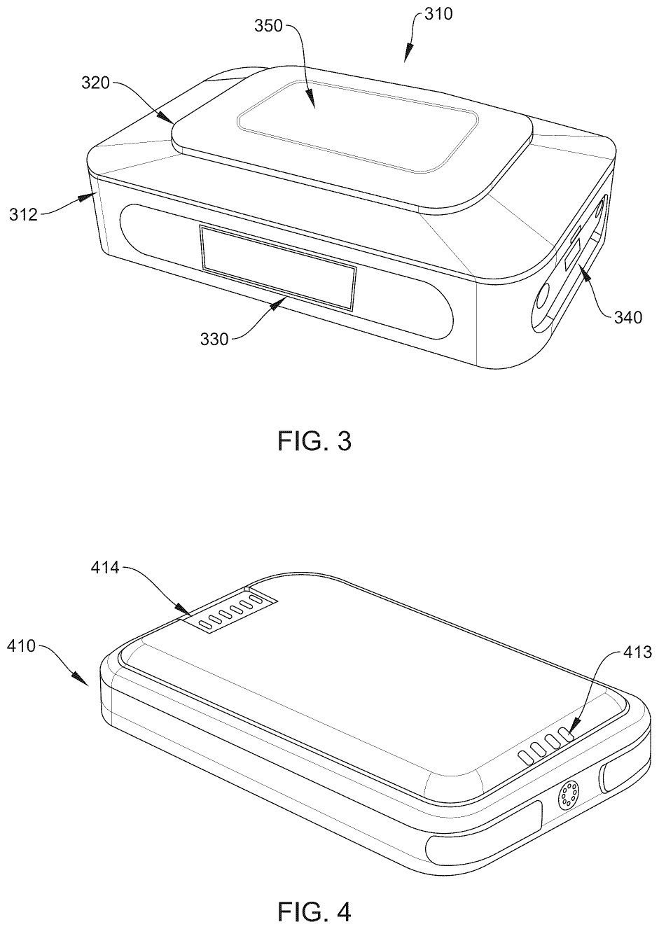

A portable power charger in accordance with another embodiment is illustrated in FIG. 3, and generally designated as reference numeral (310). The portable power charger (310) generally includes a charger housing (312) having a rechargeable battery unit (not shown) internally disposed therein. The rechargeable battery unit may be, for example, the internal power storage unit (220). The portable power charger (310) is designed for, for example, portability and convenient on-the-go use to recharge one or more mobile electronic devices.

The portable power charger (310) is also designed for easy and flexible recharging of the internal rechargeable battery unit from a variety of power sources so that it can be easily charged up to have sufficient battery capacity when it is needed to recharge a portable electronic device. Preferably, the rechargeable battery unit of the portable power charger (310) is capable of being recharged in a variety of manners, including via direct connection, such as ports (340), and via wireless connection, such as wireless charging interface. For example, to charge the rechargeable battery unit, the charger (310) may be connected with an external power source via a power input connector cable interface provided with the charger (310); via direct connection with an external power source via a separate connector cable that engages a power connection port interface (340) provided on the charger housing (312); or via wireless power transmission means. A portable power charger (310) can include any or all of these recharging features in various combinations.

Similarly, the portable power charger (310) can be used to power a small appliance or to recharge one or more electronic devices in a variety of manners, including via direct connection and via wireless connection. For example, to use the portable charger (310) to power a small appliance or recharge an electronic device, the charger (310) may be connected with a small appliance or an electronic device via a power output connector cable interface provided with the charger (310); via direct connection with the small appliance or the electronic device via a separate connector cable that engages a power connection port interface (340) provided on the charger housing (312); or via wireless power transmission means. A portable power charger (310) can include any or all of these recharging features in various combinations.

Referring to the embodiment illustrated in FIG. 3, the portable power charger (310) also has the capability of charging other devices or being recharged itself via wireless transmissions, or via direct connections, either using connector cables provided with and stored in the charger housing (312), or via separate connector cables attachable to the charger (310) via power connection ports (340) provided on the charger housing (312). In this regard, the portable power charger (310) can be used on-the-go to charge one or more electronic devices by various means and combination of means.

As noted, the portable power charger (310) of the illustrated embodiments includes the capability of charging electronic devices and small appliances via wireless power transmission. In this regard, the portable power charger (310) includes a wireless transmitter for transmitting a charge to an electronic device or small appliance. In alternative or additional embodiments, the portable power charger 10 may also include a wireless receiver for receiving a charge from a wireless charging mat or power transmitting device allowing the charger unit (310) to be recharged either wirelessly or via direct connection to an external power source, and at the same time be connected to multiple electronic devices by both wireless and direct connection means such as disclosed in U.S. Pat. No. 9,318,915, incorporated herein by reference.

The wireless transmitter of the portable power charger (310) generally comprises a magnetic induction coil (not shown) operatively connected to the internal battery unit. As shown, a wireless transmission area (350) generally aligned with the transmitter coil is illustrated on the top face of the charger housing (312). When an electronic device or a small appliance that includes a wireless receiver is aligned with the wireless transmission area (350), a magnetic field generated by the transmitter is transmitted to the receiver of the electronic device or small appliance, where a voltage is induced to power the electronic device/small appliance or recharge its internal battery, if available. In this regard, the designated wireless transmission area (350) is preferably visible to the user or at least easily ascertained so as to facilitate proper alignment and wireless charging.

The portable power charger (310) may also include a display (330) in order to provide status information and other details. The display (330) can indicate the amount of power being supplied to the portable power charger (310) (Input), the amount of power being supplied by the portable power charger (310) (Output), the amount of energy battery power remaining, etc. In alternative embodiments, the display (330) may be shown as a status light or lights, such as a series of LEDs to indicate the amount of energy battery power remaining.

FIG. 4 shows a perspective view of another embodiment of a portable power charger (410). The portable power charger (410) includes series of LEDs (413) to indicate the amount of energy battery power remaining. The LEDs (413) may also be configured to change color and/or flash to indicate various status conditions, e.g., flashing red when below 10% battery power, showing blue when charging, etc. The portable power charger (410) also includes power connection ports (414) which may be configured to interface with an attached device. This can help ensure the device is properly connected both physically and electronically.

The portable power charger (110), (200), (310), (410) described above may include any number and combination of components. For example, a portable power charger may include jumper cables, a safety circuit, a connector, and a wireless transmission area. In another example, a portable power charger may include jumper cables, a safety circuit, a connector, and a display.

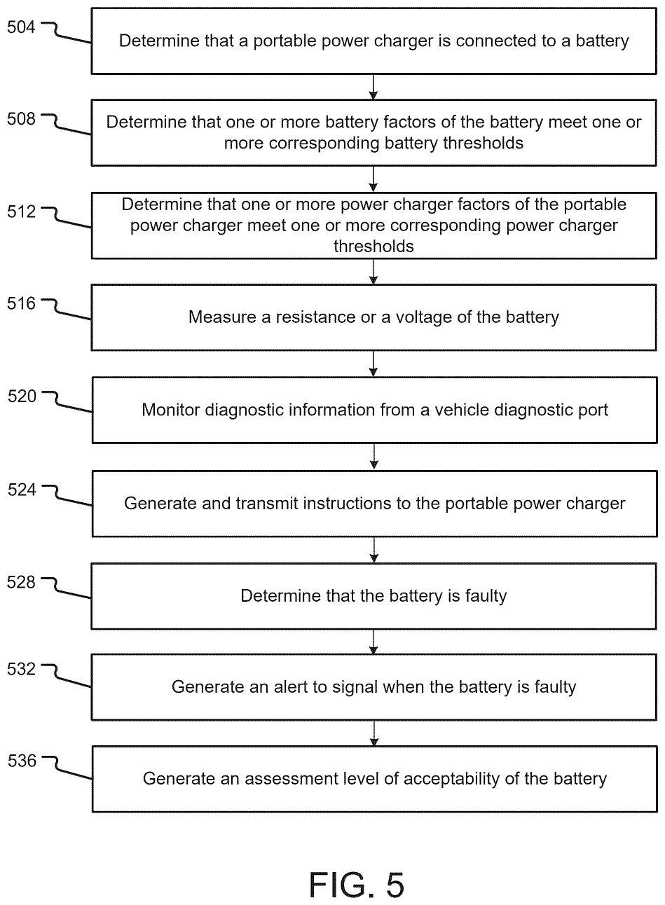

Turning to FIG. 5, a flowchart illustrating a method for generating an alert using a portable power charger is shown. The portable power charger may be the same as or similar to the portable power charger (110), (200), (310), (410) described above.

At step 504, the method includes determining that the portable power charger is connected to a battery. The battery may be, for example, a vehicle battery. The portable power charger may include jumper cables such as jumper cables (130), (132) that each include a corresponding connector such as the connectors (131), (133) that are operable to be connected to terminals of the battery. Once the connectors are physically connected to the terminals of the battery, a safety circuit such as the safety circuit (215) can determine whether the connectors are sufficiently connected to the terminals of the battery. In some embodiments, the connectors and the jumper cables can include auto-sensing spark prevention and sensing circuitry that can detect whether the connectors are sufficiently connected to the terminals of the battery.

At step 508, the method includes determining that one or more battery factors of the battery meet one or more corresponding battery thresholds. The one or more battery factors may include, for example, a temperature, a charge, a voltage, an impedance, a resistance, a current, etc. The one or more battery factors may also include results of conducting a load test or any other testing of the battery. The one or more corresponding battery thresholds may include, for example, a temperature threshold, a charge threshold, a voltage threshold, an impedance threshold, a resistance threshold, a current threshold, a load threshold, or the like. The one or more corresponding battery thresholds may be based on a type and/or rating of the battery.

The determination of whether the one or more battery factors meet the one or more corresponding battery thresholds may be executed by, for example, the safety circuit.

At step 512, the method includes determining that one or more power charger factors of the portable power charger meet one or more corresponding power charger thresholds. The one or more power charger factors may include, for example, a temperature, a charge, a voltage, an impedance, a resistance, a current, etc. of an internal power storage unit such as the internal power storage unit (220) of the portable power charger. The one or more power charger factors may also include results of conducting a load test or any other testing of the internal power storage unit. The one or more corresponding power charger thresholds may include, for example, a temperature threshold, a charge threshold, a voltage threshold, an impedance threshold, a resistance threshold, a current threshold, a load threshold, or the like. The one or more corresponding power charger thresholds may be based on a type and/or rating of the internal power storage unit.

The determination of whether the one or more power charger factors meet the one or more corresponding power charger thresholds may be executed by, for example, the safety circuit.

At step 516, the method includes measuring a resistance and/or a voltage of the battery. The resistance and/or the voltage can be measured by, for example, a resistance analysis circuit such as the resistance analysis circuit (217) and/or a voltage analysis circuit such as the voltage analysis circuit (219), respectively.

At step 520, the method includes monitoring diagnostic information from a vehicle diagnostic port. The vehicle diagnostic port may be part of a vehicle on-board system configured to provide on-board diagnostics (OBD). The vehicle diagnostic port may be, for example, an OBD2 port. The OBD2 port may be capable of, for example, providing a charge to a vehicle battery (e.g., 12V/4 A or 24V/2 A (48 W)) and can provide various diagnostic information for components in the vehicle. The diagnostic information may include, for example, one or more codes, errors, or shut-off conditions. For example, the code or the error may indicate that the vehicle battery needs to be jump started, reconditioned, and/or charged. The diagnostic information can also be used to monitor the battery charging provided by the portable power charger, which can be used to shut off the portable power charger as described below.

At step 524, the method includes generating and transmitting instructions to the portable power charger. The instructions may be generated and transmitted when the diagnostic information should preclude any charging operation by the portable power charger. In other words, the instructions may be generated and transmitted when the diagnostic information indicates that the charging operation may damage the battery, any components of the battery or vehicle, or is generally operating in an unsafe manner. The instructions may enable the portable power charger to inhibit or suspend any charging operations including any trickle charging when the diagnostic information precludes any charging operations.

It will be appreciated that in some embodiments, the method may not include the steps 520 and/or 524.

At step 528, the method includes determining that the battery is faulty. In at least one embodiment, determining that the battery is faulty includes determining that the battery is defective and/or needs reconditioning based on the measured resistance and/or the measured voltage. For example, the battery may be defective when the measured resistance does not meet a predetermined resistance threshold and/or the measured voltage does not meet a predetermined voltage threshold. In another example, the resistance analysis circuit may determine that the battery is faulty based on a quantitative and qualitative measurement and a subsequent indicator.

In another example, the battery may be determined to be faulty when the measured voltage is outside of a predetermined battery operation range for operation of a functioning battery and/or the measured voltage is outside of a predetermined alternators operation range for proper operation for alternators. In such examples, the predetermined battery operation range may be between 11.5 and 12.5V and the predetermined alternators operation range may be between 13.5V and 15.0V. In other examples, the predetermined battery operation range may be less than 11.5V and/or greater than 12.5V and the predetermined alternators operation range may be less than 13.5V and/or greater than 15.0V.

At step 532, the method includes generating an alert to signal when the battery is faulty. The alert may be displayed on a display such as the display (250), (330). In such instances, the alert may be a visual alert and/or a textual alert. The alert may include, for example, an indication that the battery is faulty or the battery is acceptable. In other embodiments, the alert may be an audible alert played on a speaker. The audible alert may include, for example, an audible alarm, a tone, and a simulated or real voice.

The alert may also include an indication of an assessment of an acceptability of the battery, which will be discussed in more detail below.

At step 536, the method includes generating an assessment level of acceptability of the battery. The assessment level may be determined by, for example, the safety circuit. The assessment level may be based on, for example, the measured resistance, the measured voltage, the one or more battery factors, and/or the one or more power charger factors. The safety circuit may be configured to determine that the battery is healthy when the assessment level meets an assessment level threshold.

The method of FIG. 5 may include more or less steps than the steps described above. For example and as previously described, the method may not include the steps 520 and/or 524. Further, any of the steps or combinations of steps my be repeated. Additionally, the steps or any combination of steps may be performed in any order and/or simultaneously.

The foregoing description has been directed to particular embodiments. However, other variations and modifications may be made to the described embodiments, with the attainment of some or all of their advantages. Modifications to the above-described systems and methods may be made without departing from the concepts disclosed herein. Accordingly, the invention should not be viewed as limited by the disclosed embodiments. Furthermore, various features of the described embodiments may be used without the corresponding use of other features. Thus, this description should be read as merely illustrative of various principles, and not in limitation of the invention.

What is claimed is:

1. A portable power charger comprising:
a port configured to connect to a cable configured to connect to a battery;
a safety circuit configured to:
a) determine that the port is connected to the battery via the cable;
b) determine that one or more battery factors of the battery meet one or more corresponding battery thresholds; and
c) determine that one or more power charger factors of the portable power charger meet one or more corresponding power charger thresholds;
a resistance analyzer configured to measure a resistance of the battery; and
an alert generator configured to generate an alert to signal when the battery is faulty based on the measured resistance.

2. The portable vehicle power bank of claim 1, further comprising a display configured to display the alert, wherein the alert comprises at least one of: a visual alert and text.

3. The portable power charger of claim 2, wherein the alert comprises an indication of at least one of the battery is faulty and the battery is acceptable.

4. The portable power charger of claim 2, wherein the display also displays an indication of an assessment of an acceptability of the battery.

5. The portable power charger of claim 1, wherein the safety circuit is further configured to generate an assessment level of acceptability of the battery, and
wherein the safety circuit is configured to determine that the battery is healthy when the assessment level meets a threshold.

6. The portable power charger of claim 1, further comprising a speaker configured to play the alert, wherein the alert comprises at least one of: an audible alarm, a tone, and a simulated or real voice.

7. The portable power charger of claim 1, wherein the resistance analyzer is configured to determine that the battery is faulty based on a) at least one of: a quantitative and qualitative measurement and b) a subsequent indicator.

8. The portable power charger of claim 1, wherein determining that the battery is faulty comprising determining that the battery is at least one of: defective and requires reconditioning.

9. The portable power charger of claim 1, wherein the battery is determined to be faulty when the measured resistance meets a resistance threshold.

10. The portable power charger of claim 1, further comprising a wireless communication system configured to perform remote monitoring of the portable power charger and the battery.

11. The portable power charger of claim 10, wherein the wireless communication system is at least one of: a Bluetooth system and a Wi-Fi system.

12. The portable power charger of claim 1, wherein the portable power charger is at least one of: a portable jump starter and a device charger.

13. A portable vehicle power bank comprising:
a jumper-cable port configured to be connected to a vehicle battery;
a safety circuit configured to confirm that:
a) the port is properly connected to the vehicle battery;
b) the vehicle battery is healthy; and
c) the portable vehicle power bank is of sufficient health and capacity,
a voltage analyzer configured to measure a voltage of the vehicle battery; and
an alert generator configured to generate an alert to signal when the battery is faulty based on the measured voltage.

14. The portable vehicle power bank of claim 13, wherein determining that the battery is faulty comprising determining at least one of:
a) the voltage is outside a predetermined battery operation range for proper operation of a functioning battery, and
b) the voltage is outside of a predetermined alternators operation range for proper operation for alternators.

15. The portable vehicle power bank of claim 14, wherein the predetermined battery operation range is between 11.5 and 12.5V.

16. The portable vehicle power bank of claim 13, wherein the vehicle battery has a chemistry of one of: flooded/wet lead acid, SLA, AGM, 4-cell or similar regulated lithium.

17. The portable vehicle power bank of claim 13, wherein the predetermined alternators operation range is between 13.5V and 15.0V.

18. A safety adapter comprising:
a safety circuit in communication with a battery and a portable power charger, the safety circuit configured to:
a) determine that one or more battery factors of the battery meet one or more corresponding battery thresholds; and
c) determine that one or more power charger factors of the portable power charger meet one or more corresponding power charger thresholds;
a resistance analyzer configured to measure a resistance of the battery; and
an alert generator configured to generate an alert to signal when the battery is faulty based on the measured resistance.

19. The safety device of claim 18, wherein the safety circuit is in at least one of wired communication and wireless communication with the battery and the portable power charger.

20. A safety device comprising:
a port configured to connect to a cable configured to connect to a vehicle diagnostic port of a vehicle on-board system, the vehicle on-board system connected to a battery;
a safety circuit in communication with a battery configured to:
a) determine that the port is connected to the battery via the cable;
b) determine that one or more battery factors of the battery meet one or more corresponding battery thresholds; and
c) determine that one or more power charger factors of the portable power charger meet one or more corresponding power charger thresholds;
d) monitor diagnostic information from the vehicle diagnostic port; and
e) generate and transmit instructions to the portable power charger to at least one of inhibit or suspend a charge when the diagnostic information precludes the charging operation; and
a resistance analyzer configured to measure a resistance of the battery; and
an alert generator configured to generate an alert to signal when the battery is faulty based on the measured resistance.

21. The portable power charger of claim 21, wherein the diagnostic information comprises at least one or more codes, errors, or shut-off conditions.
